(19) United States
(12) Patent Application Publication
(10) Pub. No.: US 2026/0305179 A1
(43) Pub. Date: Oct. 1, 2026

(54) DETECTION ARCHITECTURE FOR A PROBABILISTIC-BIT SPINTRONIC DEVICE

(71) Applicants: COMMISSARIAT À L'ENERGIE ATOMIQUE ET AUX ENERGIES ALTERNATIVES, PARIS (FR); Centre national de la recherche scientifique, PARIS (FR); UNIVERSITE GRENOBLE ALPES, SAINT-MARTIN-D'HERES (FR); INSTITUT POLYTECHNIQUE DE GRENOBLE, GRENOBLE (FR)

(72) Inventors: Kamal DANOUCHI, GRENOBLE (FR); Louis HUTIN, GRENOBLE (FR); Guillaume PRENAT, GRENOBLE (FR)

(21) Appl. No.: 19/533,007

(22) Filed: Feb. 6, 2026

(30) Foreign Application Priority Data
Feb. 13, 2025 (FR) 2501492

(51) Int. Cl. H10N 50/10; G06F 7/58; G11C 11/16; H03K 19/18; H10B 61/00; H10N 50/80

(52) U.S. Cl. CPC H10N 50/10; G06F 7/588; G11C 11/161; G11C 11/1673; G11C 11/1675; H03K 19/18; H10B 61/22; H10N 50/80

(57) ABSTRACT

A spintronic device includes a magnetic tunnel junction having a resistance that fluctuates between at least two distinct resistive states depending on its magnetization; a control transistor connected in series with the magnetic tunnel junction between a supply node and electrical ground; the common node between the control transistor and the magnetic tunnel junction constituting a first detection node; a capacitive element connected between the first detection node and a second detection node; a detection circuit having a first input connected to the second detection node and configured to generate a detection signal that varies depending on the resistive state of the magnetic tunnel junction from the electrical potential of the second detection node.

### CROSS-REFERENCE TO RELATED APPLICATION

This application claims priority to foreign French patent application No. FR 2501492, filed on Feb. 13, 2025, the disclosure of which is incorporated by reference in its entirety.

### FIELD OF APPLICATION

The invention relates to a probabilistic-bit spintronic device based on a stochastic unit consisting of a magnetic tunnel junction. The invention relates more specifically to a particular architecture for detecting the state of the stochastic unit that makes it possible to improve probabilistic bit read accuracy.

### BACKGROUND

A probabilistic bit generator is a device that randomly generates a bit word (0 or 1 binary outputs) based on physical or quantum phenomena, thus ensuring a determined level of randomness or entropy. Unlike conventional devices, which produce deterministic results, this type of device produces a 0 or 1 according to a probability able to be adjusted depending on the needs of the application. This type of probabilistic output is essential in fields such as cryptography, probabilistic algorithms and simulations, where the generation of random binary values guarantees the security or representativeness of calculations. This means that, rather than systematically giving a 0 or 1 deterministically, the device generates a bit word for a predetermined duration in which the distribution between 0 bits and 1 bits is able to be controlled or predefined via input parameters. For example, it would be possible to define a probability of 0.7 of obtaining a 1 and 0.3 of obtaining a 0, which would produce a distribution in a bit word in which roughly 70% of the bits are 1s and 30% are 0s. This probabilistic distribution distinguishes the probabilistic bit generator from pseudorandom number generators, because it relies on sources of physical uncertainty (such as quantum or thermal or magnetic noise), producing a true random in terms of bits.

Magnetic tunnel junction-based probabilistic bit generator devices are a promising solution for exploiting fluctuations in magnetic polarization state in such a structure. FIG. 1a illustrates the circuit diagram of a probabilistic bit generator D0 according to the prior art. The probabilistic bit generator D0 comprises a magnetic tunnel junction MTJ, a control transistor T₀ and a comparator COMP. The magnetic tunnel junction MTJ is a magnetoresistive pillar comprising a stack of layers 11, 12, 13. The stack comprises a first reference ferromagnetic layer 11 in which the direction of the magnetic polarization is set and uniform. The stack furthermore comprises a second ferromagnetic layer 13 in which the direction of the magnetic polarization is variable. The stack furthermore comprises an oxide barrier layer 12 confined between the first and second ferromagnetic layer 11, 13. The barrier layer 12 plays a crucial role in the magnetoresistive tunnelling effect, allowing electrons to pass through via quantum tunnelling. The first ferromagnetic layer 11 serves as a reference for detecting changes in magnetization in the free ferromagnetic layer 13. The operating principle of the magnetoresistive pillar MTJ is based on the change in electrical resistance as a function of the orientation of the magnetic polarization of the free ferromagnetic layer 13 with respect to the orientation of the magnetic polarization in the reference ferromagnetic layer 11. When the magnetizations of the free and reference layers 11, 13 are parallel, the electrical resistance is low, and reference is made to a low resistive state P. When the magnetizations are antiparallel, the electrical resistance is high, and reference is made to a high resistive state AP. The dimensioning of the magnetic tunnel junction MTJ is such that the magnetic moments of the layers fluctuate between various orientations under the influence of thermal fluctuations, even in the absence of an external magnetic field. These fluctuations are great enough, in relation to the energy barrier separating the two resistive states, for the magnetization no longer to be stable in a fixed direction. Reference is made here to operation in “fluctuation regime” or a “superparamagnetic” state, unlike magnetoresistive memories in which the magnetic layers retain their orientation following programming. Indeed, in a magnetoresistive memory, the energy barrier between the two resistive states is out of range of variations of thermal energy with an amplitude greater than 40xk_{B}T, where k_{B} is the Boltzmann constant and T is the operating temperature of the memory. The operation of the superparamagnetic tunnel junction MTJ is illustrated by the energy diagram in FIG. 1b, which illustrates a first resistive state P and a second resistive state AP separated by an energy barrier ΔE less than or equal to ten times the thermal energy k_{B}T, where k_{B} is the Boltzmann constant and T is the operating temperature of the generator D0. The respective probability of the magnetic tunnel junction MTJ generating 0 bits (high resistive state or vice versa, depending on the convention chosen) and 1 bits (low resistive state or vice versa, depending on the convention chosen) depends on the intensity of the bias current Ic passing through it. The intensity of the current Ic is regulated by the control transistor T₀ connected in series with the magnetic tunnel junction MTJ between a supply node supplying the supply voltage VDD and electrical ground GND. The common node between the magnetic tunnel junction MTJ and the control transistor T₀ forms a first detection node NC1. The comparator COMP is configured to compare the voltage drop across the magnetic tunnel junction, corresponding to the electrical potential V_{DIV} of the first detection node NC1, with a reference voltage V_{REF}, in order to continuously determine the random resistive state of said magnetic tunnel junction.

The bias current Ic is controlled by the input voltage Vᵢₙ applied to the gate of the control transistor T₀. The input voltage Vᵢₙ is advantageously chosen so as to operate in linear regime or in ohmic regime. Increasing the input voltage Vᵢₙ causes the bias current Ic to increase. Increasing the bias current Ic makes the probability P(1) of having a high resistive state AP (conventionally and non-limitingly equivalent to a “1” bit) increase. Conversely, decreasing the bias current Ic makes the probability P(0) of having a low resistive state P (conventionally and non-limitingly equivalent to a “0” bit) increase.

In this context, a major technical problem is encountered, namely the common-mode drift of the variable electrical potential of the first detection node NC1 in combination with the small amplitude of the variations of the electrical potential V_{DIV} of the first detection node NC1. In order to understand the technical problem, FIG. 1c illustrates the variation of the various signals of the probabilistic bit generator D0 in response to a decreasing linear variation of the input voltage Vᵢₙ. Let Vᵢₙ, ₘᵢₙ be the control voltage that makes it possible to obtain the distribution P(0)=99% P(1)=1%, where P(0) is the probability of having a 0 bit and P(1) is the probability of having a 1 bit. Let Vᵢₙ, ₘₐₓ be the control voltage that makes it possible to obtain the distribution P(0)=1% P(1)=99%. The input voltage Vᵢₙ varies in linearly decreasing fashion between Vᵢₙ, ₘₐₓ and Vᵢₙ, ₘᵢₙ. The variation of the input voltage Vᵢₙ induces a variation of the resistance of the superparamagnetic tunnel junction MTJ between a high state and a low state with a probability distribution that depends on the amplitude of the input voltage Vᵢₙ. This induces the variation of the voltage V_{DIV} of the first detection node NC1 between a high state and a low state. A signal V_{DIV} that varies between two voltage values is thus obtained. It has been observed that the common mode Cₘₘ of the voltage V_{DIV} is not constant, since it is inversely proportional to the input voltage Vᵢₙ. The dependence of the common mode Cₘₘ on the input voltage Vᵢₙ induces a drift of the envelope of the voltage V_{DIV} with respect to the constant reference voltage V_{REF}. In addition, the range of variation of the detection voltage V_{DIV} between the two states is limited, with an amplitude less than 20 mV. The phenomenon of common-mode Cₘₘ drift in combination with the narrow dynamic range of the detection voltage V_{DIV} means that the comparison function is no longer reliable due to the uncoupling of said detection signal with respect to the reference voltage V_{REF}, as illustrated on the detection signal Vₒᵤₜ from the uncoupling time t₁.

### SUMMARY OF THE INVENTION

To overcome the limitations of existing solutions, the invention proposes a spintronic device having a detection chain comprising a capacitive element C1 between a first detection node and a second detection node and a detection circuit receiving the potential of the second detection node. Unlike traditional generators, the proposed detection architecture neutralizes the effects of common-mode drift of the voltage at the detection node connected directly to the magnetic tunnel junction. This approach guarantees more reliable bit reading over the entire dynamic range of the input voltage Vᵢₙ or input current Iᵢₙ. The innovation results in a significant improvement in reliability, detection accuracy and robustness with regard to phenomena of process and temperature variability, thus surpassing existing solutions.

The invention relates to a spintronic device comprising:
a magnetic tunnel junction having a resistance that fluctuates between at least two distinct resistive states depending on its magnetization;
a control transistor connected in series with the magnetic tunnel junction between a supply node and electrical ground; the common node between the control transistor and the magnetic tunnel junction constituting a first detection node;
a capacitive element connected between the first detection node and a second detection node;
a detection circuit having a first input connected to the second detection node and configured to generate a detection signal that varies depending on the resistive state of the magnetic tunnel junction from the electrical potential of the second detection node.

According to one particular aspect of the invention, the detection circuit is configured to compare the electrical potential of the second detection node with a predetermined threshold voltage.

According to one particular aspect of the invention, the device furthermore comprises a first bias transistor connected between the second detection node and the supply node; the first bias transistor being controlled by a first bias voltage applied to its gate and chosen so as to keep the first bias transistor in saturation regime.

According to one particular aspect of the invention, the device furthermore comprises a computer circuit configured to generate a probabilistic bit from the detection signal based on sampling or averaging by determining the proportion of each resistive state of the magnetic tunnel junction during a predetermined period.

According to one particular aspect of the invention, the magnetic tunnel junction is a superparamagnetic tunnel junction.

According to one particular aspect of the invention, the magnetic tunnel junction is arranged on a write track made of a spin Hall effect material or an orbital Hall effect material.

According to one particular aspect of the invention, the detection circuit is an inverter and the predetermined threshold voltage is the switching threshold of said inverter.

According to one particular aspect of the invention, the detection circuit is a comparator having a first input connected to the second detection node and a second input intended to receive a reference voltage and an output node for generating the detection signal.

According to one particular aspect of the invention, the device furthermore comprises a second bias transistor connected between the second input of the comparator and the supply node; the gate of the second bias transistor being connected to the first detection node.

According to one particular aspect of the invention, the capacitance of the capacitive element is less than or equal to 20 pF.

According to one particular aspect of the invention, the capacitance of the capacitive element is between 5 pF and 10 pF.

According to one particular aspect of the invention, the magnetic tunnel junction comprises:
a first reference ferromagnetic layer in which the direction of the magnetic polarization is set;
a second ferromagnetic layer in which the direction of the magnetic polarization is variable;
an oxide tunnel barrier layer confined between the first and second ferromagnetic layer.

According to one particular aspect of the invention, the thickness of the second layer is less than 100 nm.

According to one particular aspect of the invention, the diameter of the magnetic tunnel junction is less than 10 nm.

According to one particular aspect of the invention, the device furthermore comprises a current mirror, said current mirror comprising a first supply branch coupled to a second supply branch; the second supply branch comprising at least the series-connected control transistor and magnetic tunnel junction.

### BRIEF DESCRIPTION OF THE DRAWINGS

Further features and advantages of the present invention will become more clearly apparent upon reading the following description, with reference to the following appended drawings.

FIG. 1a illustrates a probabilistic bit generator D0 according to the prior art. This figure has already been described.

FIG. 1b illustrates an energy diagram of the probabilistic bit generator D0 according to the prior art. This figure has already been described.

FIG. 1c illustrates the variation of the various signals of the probabilistic bit generator according to the prior art in response to a linear variation of the input voltage. This figure has already been described.

FIG. 2a illustrates a probabilistic bit generator D1 according to a first

embodiment of the invention.

FIG. 2b illustrates the variation of the various signals of the probabilistic bit generator according to a first embodiment of the invention in response to a linear variation of the input voltage.

FIG. 3 illustrates a probabilistic bit generator D1 according to a second embodiment of the invention.

FIG. 4a illustrates a probabilistic bit generator D1 according to a third embodiment of the invention.

FIG. 4b illustrates the variation of the various signals of the probabilistic bit generator according to a third embodiment of the invention in response to a linear variation of the input voltage.

FIG. 5 illustrates a probabilistic bit generator D1 according to a fourth embodiment of the invention.

FIG. 6 illustrates a probabilistic bit generator D1 according to a fifth embodiment of the invention.

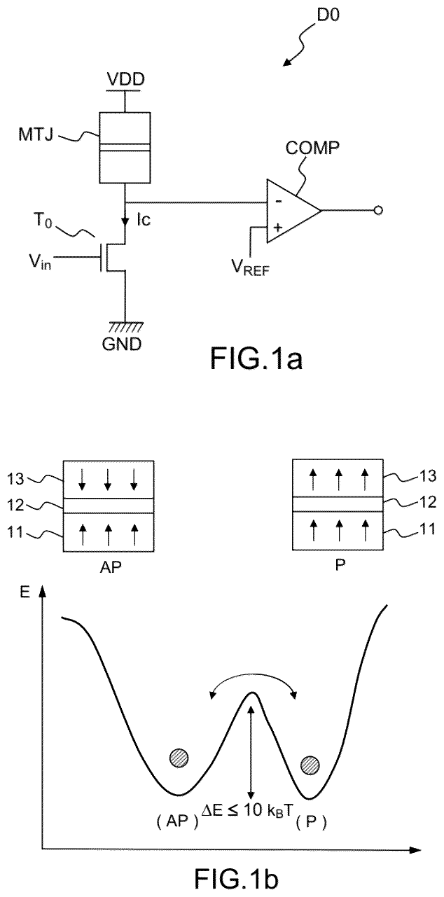

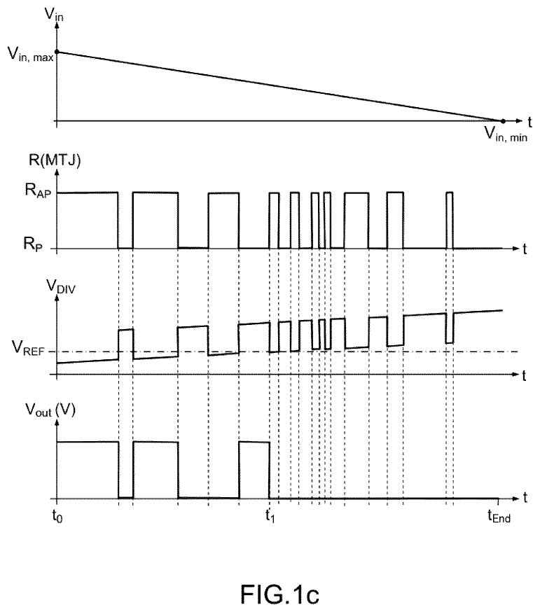

### DETAILED DESCRIPTION

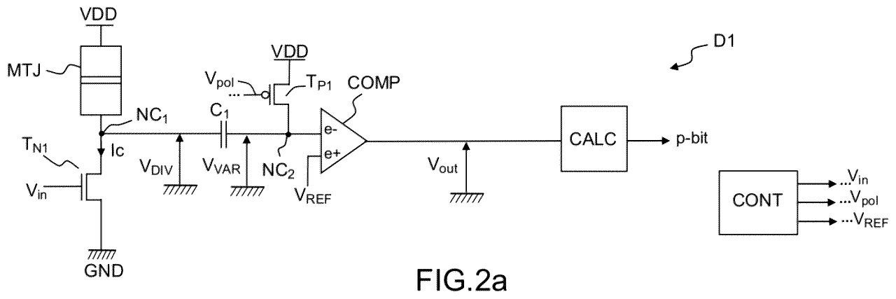

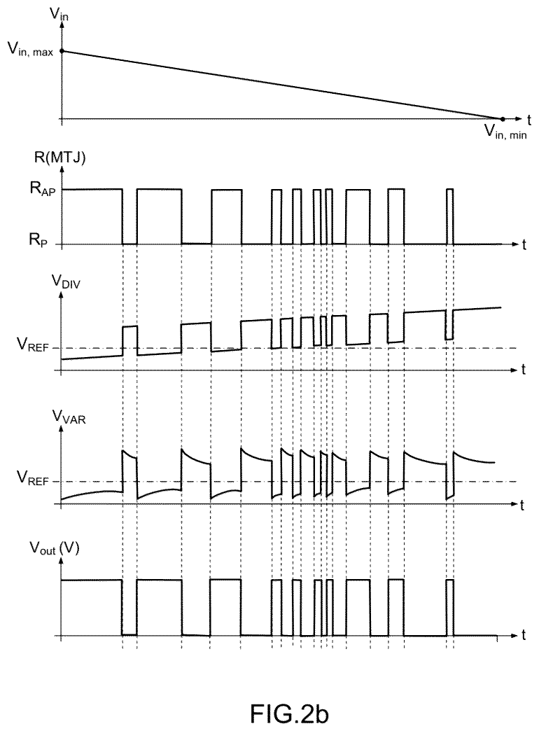

FIG. 2a illustrates a spintronic device, and more particularly a probabilistic bit generator D1 according to a first embodiment of the invention. The probabilistic bit p-bit generator D1 comprises a magnetic tunnel junction MTJ, a control transistor T_{N1}, a detection circuit COMP, a computer circuit CALC and a capacitive element C₁. The magnetic tunnel junction MTJ is dimensioned so as to operate in fluctuation regime in response to thermal agitation. The magnetic tunnel junction MTJ is formed by a stack of layers. The stack comprises a first reference ferromagnetic layer 11 in which the direction of the magnetic polarization is set and uniform. The stack furthermore comprises a second ferromagnetic layer 13 in which the direction of the magnetic polarization is variable. The stack furthermore comprises an oxide barrier layer 12 confined between the first and second ferromagnetic layer 11, 13. The diameter (or diagonal, depending on the shape) of the magnetic tunnel junction MTJ is less than 100 nm. More advantageously, the thickness of the second layer 13 is less than 10 nm, preferably less than 5 nm. This makes it possible to lower the energy barrier separating the first resistive state P and the second resistive state AP to a value less than or equal to ten times the thermal energy k_{B}T, and therefore to produce a superparamagnetic tunnel junction MTJ. It will be recalled that a superparamagnetic tunnel junction has a fluctuating resistive state in which magnetization is unstable under thermal influence.

By way of non-limiting illustration, the control transistor T_{N1} is an NMOS field-effect transistor. The control transistor T_{N1} is configured to inject a control current Ic through the magnetic tunnel junction MTJ so as to control the distribution between the two resistive states of the superparamagnetic tunnel junction MTJ. The control transistor T_{N1} is connected in series with the magnetic tunnel junction MTJ between a supply node supplying the supply voltage VDD and electrical ground GND. Increasing the bias current Ic makes the probability P(1) of having a high resistive state AP (equivalent to a “1” bit) increase. Conversely, decreasing the bias current Ic makes the probability P(0) of having a low resistive state P (equivalent to a “0” bit) increase. The bias current Ic is controlled by applying an input voltage Vᵢₙ to the gate of the control transistor T_{N1}. The generator D1 comprises control means CONT configured to apply the variable input voltage Vᵢₙ to the gate of the control transistor T_{N1}. Advantageously, the range of variation of the input voltage Vᵢₙ is chosen such that the control transistor operates in ohmic regime so as to ensure linear behaviour of the generator.

The common node between the control transistor T_{N1} and the magnetic tunnel junction MTJ forms a first detection node NC1. The potential V_{DIV} of the first detection node NC1 varies in square waves in accordance with the voltage drop across the magnetic tunnel junction MTJ, which depends on the resistance value of said junction. When the magnetic tunnel junction MTJ is in a high resistive state AP, the voltage V_{DIV} is at a low voltage, and when the magnetic tunnel junction MTJ is in a low resistive state P, the voltage V_{DIV} is at a high voltage. The capacitive element C1 is connected between the first detection node NC1 and a second detection node NC2. The detection circuit DET is configured to generate a detection signal Vₒᵤₜ that varies depending on the resistive state of the magnetic tunnel junction MTJ from the potential V_{VAR} of the second detection node NC2. The detection circuit DET is configured to compare the potential V_{VAR} of the second detection node NC2 with a predetermined threshold voltage. This set-up makes it possible to solve the problem of lack of detection accuracy due to drift of the potential V_{DIV} of the first detection node. Indeed, the capacitive element C1 makes it possible to eliminate the dependence of the common mode Cₘₘ of the input voltage Vᵢₙ on the second detection node NC2. The capacitive element C1 filters low-frequency variations corresponding to drift and lets through high-frequency variations corresponding to fluctuations in the resistive state of the tunnel junction MTJ. The signal V_{VAR} of the second detection node NC2 thus reproduces the variations of the voltage V_{DIV} by charging and discharging the capacitive element C1 while still keeping it in a common mode Cₘₘ. The fact that the detection circuit uses the potential V_{VAR} of the second detection node NC2 thus makes it possible to detect variations of the resistive state of the junction over the entire range of variation of the input signal Vᵢₙ, given that the signal V_{VAR} of the second detection node NC2 is always centred around the predetermined threshold voltage.

Advantageously, the capacitive element C1 has a capacitance less than or equal to 20 pF in order to be able to track the rapid variations of the voltage V_{DIV} resulting from fluctuations in the resistance R(MTJ) of the magnetic tunnel junction MTJ. A capacitance greater than 20 pF means that the circuit takes longer to adapt to changes, resulting in potential drift over time, since the capacitive element C1 accumulates charge and discharges more slowly compared to the fluctuations in the magnetic tunnel junction MTJ.

More advantageously, the capacitive element C1 has a capacitance greater than or equal to 5 pF and less than or equal to 10 pF. This specific range makes it possible to have a compromise between efficient filtering of common-mode Cₘₘ drift of the voltage V_{DIV}, on the one hand, and a time constant short enough to be able to track the frequency of fluctuations in the resistance R(MTJ), on the other hand.

In the first embodiment, the detection circuit DET consists of a comparator COMP. The comparator COMP comprises a first input e-connected to the second detection node NC2; and a second input receiving the reference voltage V_{REF}. In the example illustrated and without limitation, the first input e− is the inverting input of the comparator, and the second input e+ is the non-inverting input. Thus, when the magnetic tunnel junction MTJ is in a high resistive state AP, the voltage received by the first input of the comparator is less than the reference voltage V_{REF}, and the comparator generates a detection signal Vₒᵤₜ equal to VDD, equivalent to a bit equal to “1”. When the magnetic tunnel junction MTJ is in a low resistive state P, the voltage received by the first input of the comparator is greater than the reference voltage V_{REF}, and the comparator generates a detection signal Vₒᵤₜ equal to 0, equivalent to a bit equal to “0”.

FIG. 2b illustrates the variation of the various signals of the probabilistic bit generator D1 according to a first embodiment of the invention in response to a linear variation of the input voltage Vᵢₙ. The input voltage Vᵢₙ varies in linearly decreasing fashion between the values Vᵢₙ, ₘₐₓ and Vᵢₙ, ₘᵢₙ defined above. The resistance R(MTJ) of the magnetic tunnel junction MTJ fluctuates between the two resistive states R_{AP} and R_{P} with a probability that depends on the input voltage Vᵢₙ. The voltage V_{DIV} on the first detection node NC1 inversely tracks the fluctuations in the resistance R(MTJ), while staying away from the reference voltage V_{REF}. The voltage V_{VAR} on the second detection node NC2 reproduces the variations of the voltage V_{DIV} while remaining centred on the reference voltage V_{REF} by virtue of the capacitive element C1. The comparator COMP therefore generates a detection signal Vₒᵤₜ that reproduces the variations of the resistance R(MTJ) over the entire dynamic range [Vᵢₙ, ₘᵢₙ-Vin, ₘₐₓ].

The computer circuit CALC is configured to generate a probabilistic bit from the detection signal Vₒᵤₜ by determining the proportion of each resistive state of the magnetic tunnel junction MTJ during a predetermined period. The computer circuit is configured to compute the distribution between bits in a high logic state “1” and bits in a low logic state “0” in a bit sequence corresponding to the detection signal Vₒᵤₜ for a predetermined duration. For example, the computer circuit CALC is configured to sample the detection signal Vₒᵤₜ every 1 ns during a period of 10μs. The number of bits at “1” (or bits at “0”) is computed during the period of 10μs, this corresponding to a sample of 10000 logic bits to determine the proportion of bits at “1” and at “0”, this corresponding to the probabilistic bit p-bit=(P(1), P(0)).

As an alternative, the computer circuit CALC is configured to compute the average of the detection signal s1 over the duration of the period. The average is proportional to the number of bits equal to “1” over the sampled period.

Advantageously, the probabilistic bit generator D1 furthermore comprises a first bias transistor T_{P1} connected between the second detection node NC2 and the supply node VDD. The first bias transistor T_{P1} is controlled by a first bias voltage Vₚₒₗ applied to its gate. The first bias voltage Vₚₒₗ is generated by the control means CONT, and is chosen so as to keep the first bias transistor T_{P1} in saturation regime. The first bias transistor T_{P1} is dimensioned and biased in such a way as to bias the common mode of the voltage V_{VAR} at a value in the range [0.9xV_{REF}; 1.1xV_{REF}].

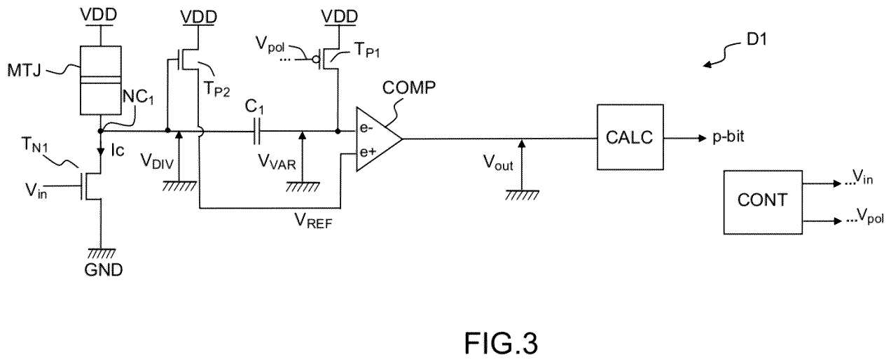

FIG. 3 illustrates a probabilistic bit generator D1 according to a second embodiment of the invention. The second embodiment has the same technical features and advantages described in detail for the first embodiment. The generator D1 according to the second embodiment furthermore comprises a second bias transistor T_{P2} connected between the second input of the comparator COMP and the supply node VDD. The gate of the second bias transistor T_{P2} is connected to the first detection node NC1. The bias transistor T_{P2} is dimensioned so as to operate in saturation regime in response to the voltage V_{DIV} that controls its gate. The drain of the second bias transistor T_{P2} thus supplies a reference voltage V_{REF} to the comparator COMP that is less sensitive to phenomena of process and/or temperature variability. Indeed, process variability in an integrated circuit stems from unavoidable manufacturing variations, such as the dimensions of the transistors or the dopants. Temperature variability results from local heating differences arising from component activity and heat dissipation. These factors influence circuit performance and reliability by creating different responses in one and the same circuit. Given that a stochastic circuit comprises a plurality of spintronic devices according to the invention, variability problems must be taken into account in the design stage. Unlike a conventional reference voltage, the reference voltage V_{REF} in the circuit of the invention is specific to the device being measured. The reference is extracted directly from the device itself. This means that the reference voltage is correlated to the device, and that its variations affect the entire system in a similar way, thereby limiting errors. In the event of differences arising from manufacturing processes or temperature, the reference voltage adjusts accordingly. The probabilistic bit generator D1 according to a second embodiment thus makes it possible to mitigate problems relating to variability phenomena.

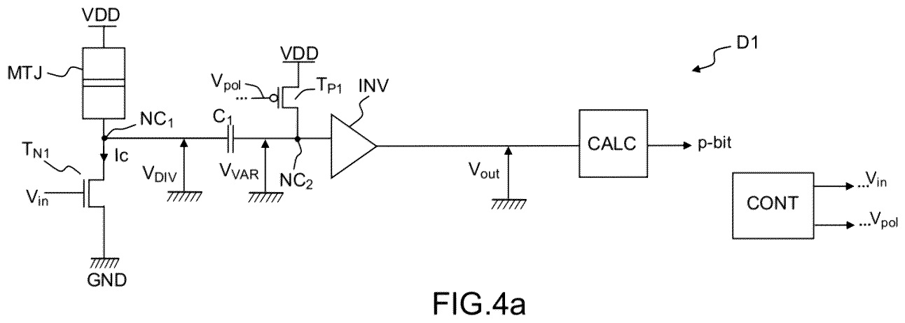

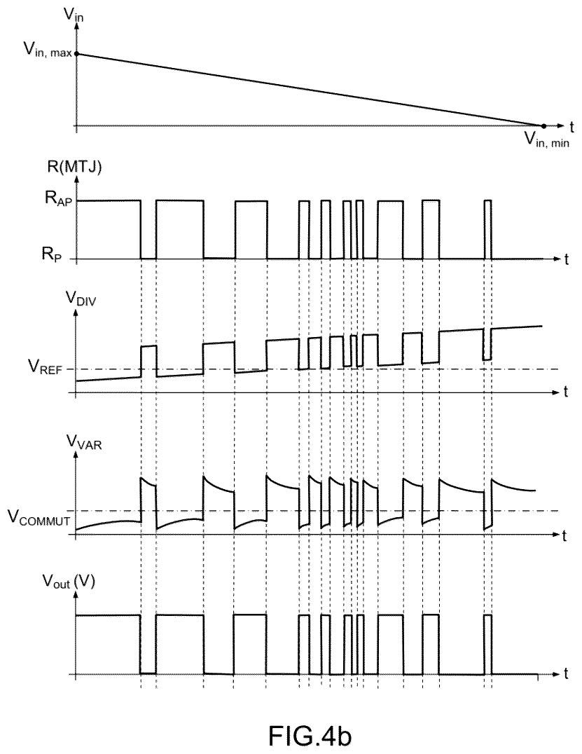

FIG. 4a illustrates a probabilistic bit generator D1 according to a third embodiment of the invention. The third embodiment has the same technical features and advantages described in detail for the first embodiment. The generator D1 according to the third embodiment differs from the first embodiment through the implementation of the detection circuit DET. The detection circuit DET consists of an inverter in place of the comparator COMP. The inverter INV comprises an input e1 connected to the second detection node NC2. When the magnetic tunnel junction MTJ is in a high resistive state AP, the voltage received by the inverter is less than its intrinsic switching threshold voltage V_{COMMUT}. The inverter INV generates, on its output, a detection signal Vₒᵤₜ equal to VDD, equivalent to a bit equal to “1”. When the magnetic tunnel junction MTJ is in a low resistive state P, the voltage received by the inverter is greater than its switching voltage V_{COMMUT}, and the inverter generates a zero detection signal Vₒᵤₜ, equivalent to a bit equal to “0”.

FIG. 4b illustrates the variation of the various signals of the probabilistic bit generator D1 according to a third embodiment of the invention in response to a linear variation of the input voltage Vᵢₙ. The probabilistic bit generator D1 according to the third embodiment exhibits behaviour similar to the response described in FIG. 2b. The voltage V_{VAR} on the second detection node NC2 reproduces the variations of the voltage V_{DIV} while remaining centred on the switching voltage V_{COMMUT} by virtue of the capacitive element C1. The inverter INV therefore generates a detection signal Vₒᵤₜ that reproduces the variations of the resistance R(MTJ) over the entire dynamic range [V_{in,min}-V_{in,max}].

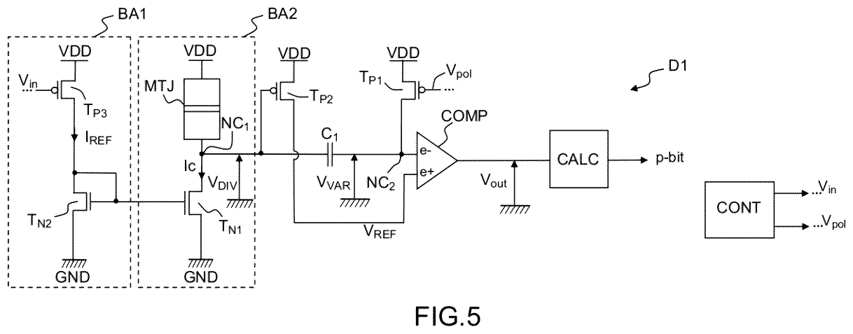

FIG. 5 illustrates a probabilistic bit generator D1 according to a fourth embodiment of the invention. The fourth embodiment has the same technical features and advantages described in detail for the first embodiment. The generator D1 according to the fourth embodiment comprises a current mirror capable of copying a reference current through the magnetic tunnel junction MTJ with high accuracy. The current mirror comprises a first supply branch BA1 coupled to a second supply branch BA2. The first branch comprises a PMOS transistor T_{P3} connected in series with a diode-connected NMOS transistor T_{N2}. The transistor T_{P3} receives the input voltage Vᵢₙ on its gate so as to set the intensity of I_{REF} passing through the first supply branch BA1. The gate of the transistor T_{N2} is connected to that of the control transistor T_{N1} in order to couple the two supply branches BA1, BA2.

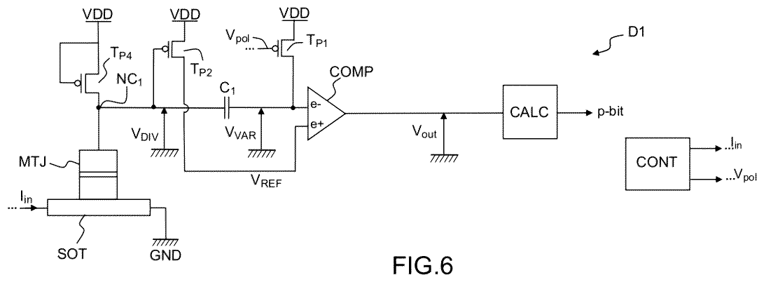

FIG. 6 illustrates a probabilistic bit generator D1 according to a fifth embodiment of the invention. The fifth embodiment has the same technical features and advantages described in detail for the previous embodiments. In the generator D1 according to the fifth embodiment, the magnetic tunnel junction MTJ is arranged on a write track SOT made of a spin Hall effect material or an orbital Hall effect material. The interface between the magnetic tunnel junction MTJ and the write track SOT is on the side of the free ferromagnetic layer. The direction of the stack forming the magnetic tunnel junction MTJ is orthogonal to the plane formed by the layer forming the write track SOT. The write track SOT is made of a spin Hall effect material (also known as a spin-orbit couple effect material), for example beta-phase tungsten or bismuth antimonide or a stack of two layers, one made of tantalum and the other of tungsten, or a BiSbTe alloy. The control means generate a write current Iᵢₙ through the write track SOT in one direction. This induces spin currents that interact with the free ferromagnetic layer. This interaction makes it possible to control the direction of magnetic polarization in the free ferromagnetic layer of the junction MTJ in accordance with the direction of the write current in the write track SOT. Controlling the direction of magnetic polarization in the free ferromagnetic layer makes it possible to modify the electrical resistance R(MTJ) of the magnetic tunnel junction MTJ without injecting a write current into it, thereby considerably increasing the robustness of the spintronic device. The resistive state is detected at the second detection node NC2, and not directly on the first detection node NC1. The capacitive element C1 makes it possible to solve read problems resulting from common-mode drift of the potential V_{DIV} at the first common node NC1.

The spintronic device according to the invention exploits the stochastic properties of a magnetic tunnel junction MTJ to produce random or pseudorandom bits with a controlled distribution. Unlike traditional generators, it uses a particular detection architecture that makes it possible to eliminate the effects of common-mode drift of the voltage at the detection node connected directly to the end of the magnetic tunnel junction MTJ. This solution enables more reliable bit reading over the entire dynamic range of the input voltage Vᵢₙ (or input current Iᵢₙ). This innovation improves reliability, detection accuracy and robustness with regard to variability phenomena compared to existing solutions.

1. A spintronic device (D1) comprising:
a magnetic tunnel junction (MTJ) having a resistance that fluctuates between at least two distinct resistive states (P, AP) depending on its magnetization;
a control transistor (T_{N1}) connected in series with the magnetic tunnel junction (MTJ) between a supply node (VDD) and electrical ground (GND); the common node between the control transistor (T_{N1}) and the magnetic tunnel junction (MTJ) constituting a first detection node (NC1);
a capacitive element (C₁) connected between the first detection node (NC1) and a second detection node (NC2); and
a detection circuit (COMP, INV) having a first input (e−) connected to the second detection node (NC2) and configured to generate a detection signal (Vₒᵤₜ) that varies depending on the resistive state of the magnetic tunnel junction (MTJ) from the electrical potential (V_{VAR}) of the second detection node (NC2).

2. The spintronic device (D1) according to claim 1, wherein the detection circuit (COMP, INV) is configured to compare the electrical potential (V_{VAR}) of the second detection node (NC2) with a predetermined threshold voltage (V_{REF}, V_{COMMUT}).

3. The spintronic device (D1) according to claim 1, further comprising a first bias transistor (T_{P1}) connected between the second detection node (NC2) and the supply node (VDD); the first bias transistor (T_{P1}) being controlled by a first bias voltage (Vₚₒₗ) applied to its gate and chosen so as to keep the first bias transistor (T_{P1}) in saturation regime.

4. The spintronic device (D1) according to claim 1, further comprising a computer circuit (CALC) configured to generate a probabilistic bit from the detection signal (Vₒᵤₜ) based on sampling or averaging by determining the proportion of each resistive state of the magnetic tunnel junction (MTJ) during a predetermined period.

5. The spintronic device (D1) according to claim 1, wherein the magnetic tunnel junction (MTJ) is a superparamagnetic tunnel junction.

6. The spintronic device (D1) according to claim 1, wherein the magnetic tunnel junction (MTJ) is arranged on a write track (SOT) made of a spin Hall effect material or an orbital Hall effect material.

7. The spintronic device (D1) according to claim 2, wherein the detection circuit (INV) is an inverter (INV) and the predetermined threshold voltage is the switching threshold (V_{COMMUT}) of said inverter.

8. The spintronic device (D1) according to claim 2, wherein the detection circuit (DET) is a comparator (COMP) having a first input connected to the second detection node (NC2) and a second input intended to receive a reference voltage (V_{REF}) and an output node for generating the detection signal (Vₒᵤₜ).

9. The spintronic device (D1) according to claim 8, further comprising a second bias transistor (T_{P2}) connected between the second input of the comparator (COMP) and the supply node (VDD); the gate of the second bias transistor (T_{P2}) being connected to the first detection node (NC1).

10. The spintronic device (D1) according to claim 1, wherein the capacitance of the capacitive element (C₁) is less than or equal to 20 pF.

11. The spintronic device (D1) according to claim 1, wherein the capacitance of the capacitive element (C₁) is between 5 pF and 10 pF.

12. The spintronic device (D1) according to claim 1, wherein the magnetic tunnel junction (MTJ) comprises:
a first reference ferromagnetic layer wherein the direction of the magnetic polarization is set;
a second ferromagnetic layer wherein the direction of the magnetic polarization is variable;
an oxide tunnel barrier layer confined between the first and second ferromagnetic layer.

13. The spintronic device (D1) according to claim 12, wherein the thickness of the second layer is less than 100 nm.

14. The spintronic device (D1) according to claim 12, wherein the diameter of the magnetic tunnel junction (MTJ) is less than 10 nm.

15. The spintronic device (D1) according to claim 1, comprising a current mirror, said current mirror comprising a first supply branch (BA1) coupled to a second supply branch (BA2); the second supply branch (BA2) comprising at least the series-connected control transistor (T_{N1}) and magnetic tunnel junction (MTJ).
